(19) United States
(12) Patent Application Publication
(10) Pub. No.: US 2026/0219988 A1
(43) Pub. Date: Jul. 30, 2026

(54) ERROR CORRECTION APPARATUS, ERROR CORRECTION METHOD, AND MEMORY SYSTEM

(71) Applicant: Kioxia Corporation, Tokyo (JP)

(72) Inventor: Takahiro KUBOTA, Kawasaki Kanagawa (JP)

(73) Assignee: Kioxia Corporation, Tokyo (JP)

(21) Appl. No.: 19/234,378

(22) Filed: Jun. 11, 2025

(30) Foreign Application Priority Data
Jan. 28, 2025 (JP) 2025-011837

(51) Int. Cl. G06F 11/10

(52) U.S. Cl. CPC G06F 11/1048; G06F 11/1068

(57) ABSTRACT

An error correction apparatus according to one embodiment includes a controller. The controller determines first likelihood information corresponding to a first received word as a target of decoding by using first correspondence information in which read values included in a received word and likelihood information are correlated with each other. The controller executes iterative processing of repeating soft-decision decoding using the first likelihood information. The controller executes update processing of updating the first correspondence information to second correspondence information when the termination condition is satisfied and the soft-decision decoding is failed. The controller calculates an evaluation value that increases with increase in a difference between the first and second correspondence information. The controller executes change processing of changing, according to the evaluation value, a first parameter for the iterative processing or a second parameter for the update processing. The controller executes further the iterative processing after the change processing.

### CROSS-REFERENCE TO RELATED APPLICATIONS

This application is based upon and claims the benefit of priority from Japanese Patent Application No. 2025-011837, filed on Jan. 28, 2025, the entire contents of which are incorporated herein by reference.

### FIELD

Embodiments described herein relate generally to an error correction apparatus, an error correction method, and a memory system.

### BACKGROUND

In a memory system, for protecting data stored in a memory such as a NAND flash memory, error-correction-encoded data is stored in the memory. When the data stored in the memory is read, the error-correction-encoded data that is read from the memory (also referred to as a received word) is decoded to restore data before the error correction encoding.

### BRIEF DESCRIPTION OF THE DRAWINGS

FIG. 1 is a block diagram of a memory system according to an embodiment;

FIG. 2 is a diagram illustrating an example of a data structure of an LLR table;

FIG. 3 is a block diagram of a decoder according to an embodiment;

FIG. 4 is a flowchart of decoding processing according to an embodiment; and

FIG. 5 is a flowchart of decoding processing according to a first modification example.

### DETAILED DESCRIPTION

An error correction apparatus according to an embodiment includes a controller. The controller is configured to determine first likelihood information being a piece of likelihood information corresponding to a first received word as a target of decoding among multiple pieces of likelihood information. The first likelihood information is determined by using first correspondence information in which read values included in a received word and the multiple pieces of likelihood information are correlated with each other. The controller is configured to execute iterative processing of repeating soft-decision decoding using the first likelihood information until a termination condition is satisfied. The controller is configured to execute update processing of updating the first correspondence information to second correspondence information in a case where the termination condition is satisfied and the soft-decision decoding is failed. The controller is configured to calculate an evaluation value that increases with increase in a difference between the first correspondence information and the second correspondence information. The controller is configured to execute change processing of changing, in accordance with the evaluation value, at least one of a first parameter to be used in the iterative processing or a second parameter to be used in the update processing. The controller is configured to execute further the iterative processing after executing the change processing.

The error correction apparatus and the error correction method according to the embodiments will be described below in detail with reference to the accompanying drawings. The present disclosure is not limited by the following embodiments. Hereinafter, an example in which the present invention is applied to error correction processing in a memory system will be mainly described. The apparatus (system) to which the present invention can be applied is not limited to the memory system, and may be applied to any other apparatus (system). For example, the present invention can be applied to a communication apparatus (communication system) including error correction processing using an error correction code such as a generalized low density parity check (GLDPC) code.

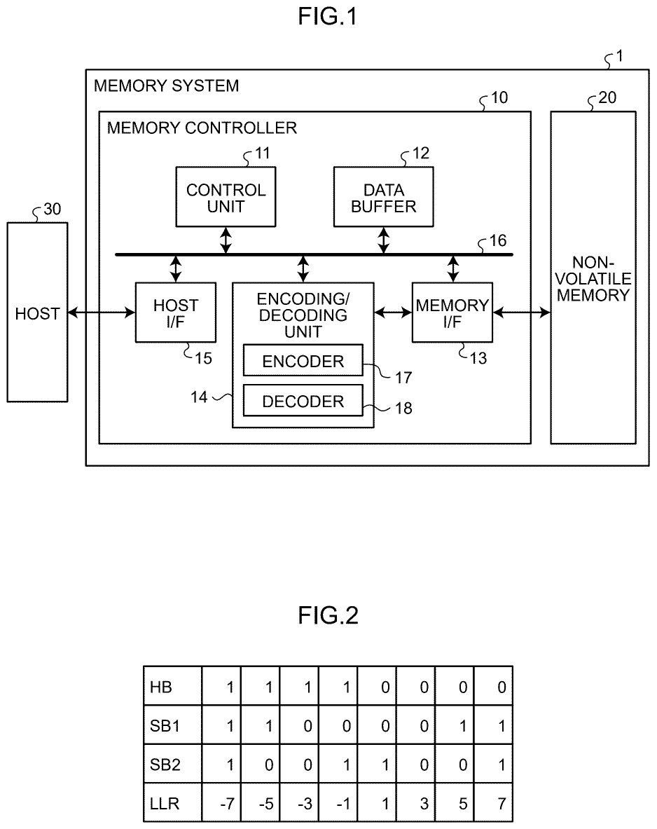

FIG. 1 is a block diagram illustrating a schematic configuration example of a memory system according to an embodiment. As illustrated in FIG. 1, a memory system 1 includes a memory controller 10 and a nonvolatile memory 20. The memory system 1 can be connected to a host 30. In FIG. 1, the memory system 1 is connected to the host 30. The host 30 may be, for example, an electronic device such as a personal computer or a mobile terminal.

The nonvolatile memory 20 is a nonvolatile memory that stores data in a nonvolatile manner, and is, for example, a NAND memory such as a NAND flash memory. In the following description, a case where a NAND memory is used as the nonvolatile memory 20 will be exemplified, but a storage device other than the NAND memory, such as a three-dimensional structure flash memory, a resistance random access memory (ReRAM), or a ferroelectric random access memory (FeRAM), can be used as the nonvolatile memory 20. The nonvolatile memory 20 is not necessarily a semiconductor memory, and the present embodiment can also be applied to various storage media other than the semiconductor memory.

The memory system 1 may be a memory card or the like in which the memory controller 10 and the nonvolatile memory 20 are configured as one package, or may be a solid state drive (SSD) or the like.

The memory controller 10 controls writing to the nonvolatile memory 20 in accordance with a write request from the host 30. The memory controller 10 controls reading from the nonvolatile memory 20 in accordance with a read request from the host 30. The memory controller 10 includes a host interface (host I/F) 15, a memory interface (memory I/F) 13, a control unit 11, an encoding/decoding unit (codec) 14, and a data buffer 12. The host I/F 15, the memory I/F 13, the control unit 11, the encoding/decoding unit 14, and the data buffer 12 are mutually connected by an internal bus 16. Some or all of the operations of each component of the memory controller 10 may be implemented by a central processing unit (CPU) executing firmware, or may be implemented by hardware.

The host I/F 15 is a circuit that performs processing compliant to the interface standard with the host 30 and outputs a command received from the host 30, user data to be written, and the like to the internal bus 16. The host I/F 15 transmits to the host 30 the user data read from the nonvolatile memory 20 and restored, a response from the control unit 11, and the like. The host I/F 15 is, for example, an interface compliant to the peripheral component interconnect (PCI) express standard.

The memory I/F 13 is a circuit that performs write processing to the nonvolatile memory 20 on the basis of an instruction from the control unit 11. The memory I/F 13 performs read processing from the nonvolatile memory 20 on the basis of an instruction from the control unit 11.

The control unit 11 integrally controls each component of the memory system 1. In a case where a command is received from the host 30 via the host I/F 15, the control unit 11 performs control according to the command. For example, the control unit 11 instructs the memory I/F 13 to write the user data and the parity to the nonvolatile memory 20 in accordance with the command from the host 30. In addition, the control unit 11 instructs the memory I/F 13 to read the user data and the parity from the nonvolatile memory 20 in accordance with the command from the host 30.

In a case where a write request of the user data is received from the host 30, the control unit 11 accumulates the user data in the data buffer 12, and decides a storage area (memory area) of the user data in the nonvolatile memory 20. Thus, the control unit 11 manages a write destination of the user data. The correspondence between a logical address of the user data received from the host 30 and a physical address indicating the storage area on the nonvolatile memory 20 where the user data is stored is stored as an address conversion table.

In a case where a read request is received from the host 30, the control unit 11 converts a logical address designated by the read request into a physical address using the above-described address conversion table, and instructs the memory I/F 13 to perform reading from the physical address.

In the NAND memory, writing and reading are generally performed in data units called pages, and erasing is performed in data units called blocks. In the present embodiment, a plurality of memory cells connected to the same word line is referred to as a memory cell group. In a case where the memory cell is a single-level cell (SLC), one memory cell group corresponds to one page. In a case where the memory cell is a multi-level cell (MLC), one memory cell group corresponds to a plurality of pages. Each memory cell is connected to a word line and is also connected to a bit line. Therefore, each memory cell can be identified by an address for identifying a word line and an address for identifying a bit line.

The data buffer 12 temporarily stores the user data received from the host 30 by the memory controller 10 until the user data is stored in the nonvolatile memory 20. The data buffer 12 temporarily stores the user data read from the nonvolatile memory 20 until the user data is transmitted to the host 30. As the data buffer 12, for example, a general-purpose memory such as a static random access memory (SRAM) or a dynamic random access memory (DRAM) can be used.

The user data transmitted from the host 30 is transferred to the internal bus 16 and temporarily stored in the data buffer 12. The encoding/decoding unit 14 encodes the user data to generate a code word. In addition, the encoding/decoding unit 14 decodes a received word which is data read from the nonvolatile memory 20, to restore the user data. Therefore, the encoding/decoding unit 14 includes an encoder 17 and a decoder 18. Note that the data encoded by the encoding/decoding unit 14 may include control data or the like used inside the memory controller 10 in addition to the user data.

Next, the write processing of the present embodiment will be described. The control unit 11 instructs the encoder 17 to encode the user data at the time of writing the user data to the nonvolatile memory 20. At that time, the control unit 11 decides a storage location (storage address) of the code word in the nonvolatile memory 20, and also instructs the decided storage location to the memory I/F 13.

The encoder 17 encodes the user data on the data buffer 12 on the basis of the instruction from the control unit 11 to generate a code word. As the encoding method, for example, an encoding method using an algebraic code such as a Bose-Chaudhuri-Hocquenghem (BCH) code and a Reed-Solomon (RS) code, and an encoding method (product code or the like) using these codes as component codes in a row direction and a column direction can be adopted. The memory I/F 13 performs control to store a code word in the storage location on the nonvolatile memory 20 instructed from the control unit 11.

Next, processing at the time of reading from the nonvolatile memory 20 of the present embodiment will be described. At the time of reading from the nonvolatile memory 20, the control unit 11 designates an address on the nonvolatile memory 20 and instructs the memory I/F 13 to perform reading. The control unit 11 instructs the decoder 18 to start decoding. The memory I/F 13 reads data from a designated address of the nonvolatile memory 20 according to an instruction of the control unit 11, and inputs the read data to the decoder 18 as a received word. The decoder 18 decodes the received word which is data read from the nonvolatile memory 20.

Next, an error correction code (code word) used in the present embodiment will be described. In the present embodiment, the encoder 17 generates a multi-dimensional error correction code as the error correction code.

The multi-dimensional error correction code refers to a code in which symbols that are at least one constituent unit of the error correction code are protected in a multiple manner by a plurality of smaller component codes. One symbol includes, for example, one bit (element of a binary field) or an element of an alphabet such as a finite field other than a binary field. Note that in order to facilitate the description, an error correction code over a binary field in which one symbol includes one bit will be described below as an example. In the present disclosure, symbols and bits may be mixed, but the both words represent the same meaning.

As an example of the multi-dimensional error correction code, a product code is exemplified. The product code has, for example, a structure in which each information symbol, which is a constituent unit of user data, is protected in both the row direction and the column direction by a BCH code including parity symbols of a predetermined parity length. Thus, in the product code, all symbols are doubly protected by component codes in the row direction (referred to as dimension 1) and the column direction (referred to as dimension 2). Note that the multi-dimensional error correction code is not limited thereto, and may be, for example, a generalized low density parity check (GLDPC) code. In the general multi-dimensional error correction code including the GLDPC code, the multiplicity of protection may be different for each symbol, and the component codes cannot be grouped as in dimension 1 and dimension 2, but the present technology can also be applied to such a code configuration.

Hereinafter, for simplicity, an example of using a two-dimensional error correction code (product code) will be described. In the two-dimensional error correction code, each symbol is protected by two component codes that can be grouped into dimension 1 and dimension 2. Each component code of each dimension includes one or more component codes determined for each dimension. Hereinafter, a component code corresponding to each dimension including one or more component codes may be referred to as a component code group. The component code group in dimension 1 includes n1 component codes, and the component code group in dimension 2 includes n2 component codes. The applicable error correction codes are not limited thereto, and may be N-dimensional error correction codes in which at least one symbol of the symbols constituting the code is protected by N component code groups (N is an integer equal to or greater than 2). In a case of being expressed in terms of the number of component codes included in each component code group, an N-dimensional error correction code is protected by M component codes (M is the total sum of ni (1≤i≤N), N is an integer equal to or greater than 2, and ni is the number of component codes in the i-th dimension).

The product code may be decoded as follows.
(A1) First, high-speed hard-decision decoding with low correction capability is performed. The hard-decision decoding is decoding using data of a hard-decision value which is binary data of 0 or 1 read from the nonvolatile memory 20. Hereinafter, the data of the hard-decision value may be referred to as hard bit data (HB data), and the hard-decision decoding may be referred to as HB decoding.
(A2) In a case where the HB decoding is failed, soft-decision decoding that is slower than the HB decoding but has high correction capability is performed. The soft-decision decoding is decoding using likelihood information (log-likelihood ratio or the like) indicating the likelihood of 0 or 1. Hereinafter, the soft-decision decoding may be referred to as soft bit (SB) decoding.

For the product code, decoding of the component code in the row direction (dimension 1) and decoding of the component code in the column direction (dimension 2) may be repeatedly executed. In the product code, SB decoding may be repeatedly executed until a termination condition is satisfied. The processing of repeating (repeating) the SB decoding may be referred to as iterative processing below. The number of times the SB decoding is repeated in one iteration of iterative processing may be referred to as the “number of iterations” below.

The decoding processing may be configured to execute a function (hereinafter, a performance improvement function) for improving the performance of the SB decoding each time when one iteration of the iterative processing is executed. Such a performance improvement function is implemented by, for example, update processing of updating the LLR table.

The LLR table is information used in the SB decoding. FIG. 2 is a diagram illustrating an example of the data structure of the LLR table. As illustrated in FIG. 2, the LLR table is correspondence information in which read values (a combination of hard bit data and soft bit data) included in the received word are correlated with pieces of likelihood information (log-likelihood ratio (LLR)). Note that FIG. 2 illustrates an example of the LLR table in a case where two pieces of soft bit data SB1 and SB2 are used. The number of pieces of soft bit data is not limited to two, and may be one or three or more.

The value of the log-likelihood ratio (LLR) may be referred to as a channel value or channel LLR data. In this manner, the channel value is decided by the LLR table in which the set of the hard bit data and the soft bit data and the channel value are correlated with each other.

The value of the LLR may be positive or negative. The LLR table includes an entry in which the sign of the value of the LLR is switched. In the example of FIG. 2, the sign of the value of the LLR is switched between the fourth entry and the fifth entry from the left among the eight entries of the LLR table. It is desirable that the value of the LLR and the position where the sign is switched are appropriately set according to the state of the channel or the like.

The update processing is, for example, processing of estimating an LLR table more suitable for a channel by using a decoding result (posterior value LLR) obtained by the iterative processing of the SB decoding and updating the LLR table used in subsequent SB decoding by the estimated LLR table.

The update processing is executed once, for example, each time one iteration of the iterative processing of the SB decoding is performed. In the initial SB decoding, an LLR table in which a value is set in advance is used as a predefined value. Hereinafter, the LLR table used as the predefined value may be referred to as a predefined LLR table. The predefined LLR table may be a general-purpose LLR table defined in common for the nonvolatile memories 20, or may be an LLR table adjusted for each nonvolatile memory 20.

A comparative example in which the update processing of the LLR table is executed will be described. In the comparative example, for example, a maximum value MaxA for the number of iterations of the iterative processing in the SB decoding and a maximum value MaxB for the number of executions (hereinafter, the number of update times) of the update processing of the LLR table are set to fixed values that are obtained by calculation in advance so as not to exceed an allowable latency. For example, in a case where the latency for 240 times of SB decoding is allowed, “60” is set as the maximum value MaxA for the number of iterations, and “4” is set as the maximum value MaxB for the number of update times.

The optimal LLR table varies depending on the state of the nonvolatile memory 20. When the difference between the predefined LLR table and the optimal LLR table is large, the optimal LLR table may not be reached even in a case where the update processing is performed a fixed number of times. Thus, in the comparative example, since the maximum value MaxB for the number of update times is a fixed value, the correction capability may not be sufficiently exhibited. In order to improve the correction capability, for example, it is desirable to increase the number of executions of the update processing by increasing the maximum value MaxB in a case where the difference between the LLR tables is large.

Considering the above, the memory system 1 according to the present embodiment calculates a difference between the predefined LLR table and the LLR table (the estimation result of the LLR table) obtained through the update processing, and changes parameters of the decoding processing such that more time is allocated to the estimation (update processing) of the LLR table when the difference is large. For example, when the difference between the LLR tables is large, the value of the parameter indicating the maximum value MaxB for the number of update times of the LLR table is increased. As a result, it is possible to obtain an LLR table closer to the optimal LLR table, namely, with high accuracy.

Meanwhile, even if the maximum value MaxB is increased, the total latency increases in a case where the maximum value MaxA for the number of iterations of the SB decoding is set as a fixed value. Then, a situation in which the total latency exceeds the allowable latency may occur. In the present embodiment, in order not to exceed the allowable latency, the value of the parameter indicating the maximum value MaxA is decreased when the difference between the LLR tables is large.

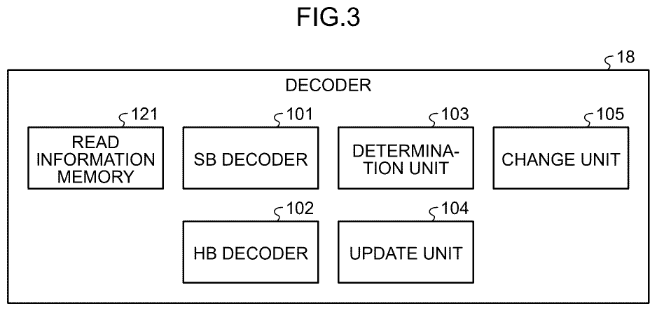

Next, a configuration example of the decoder 18 according to the present embodiment will be described. FIG. 3 is a block diagram illustrating a schematic configuration example of the decoder 18 according to the embodiment. As illustrated in FIG. 3, the decoder 18 includes a read information memory 121, an SB decoder 101, an HB decoder 102, a determination unit 103, an update unit 104, and a change unit 105.

The read information memory 121 is implemented by, for example, an SRAM. The SB decoder 101, the HB decoder 102, the determination unit 103, the update unit 104, and the change unit 105 are implemented by at least one of a register, an adder, a multiplier, and other arithmetic units. The register is implemented by, for example, a logic circuit such as a flip-flop. The adder, the multiplier, the selector, and the other arithmetic units are implemented by, for example, a logic circuit.

The read information memory 121 is a memory that stores a received word (read information) that is data read from the nonvolatile memory 20.

Among the received words, data corresponding to a hard-decision value that is binary information that decides whether each bit is 0 or 1 corresponds to the above-described hard bit data. Data corresponding to a part of the received word excluding the hard bit data corresponds to the above-described soft bit data.

In reading by soft decision (soft bit reading), one piece of hard bit data and a plurality of pieces of soft bit data are obtained. One piece of hard bit data is obtained by using the same read voltage (hereinafter, referred to as VrH) as the read voltage used for reading by hard decision (hard bit reading). The pieces of soft bit data are obtained by using read voltages including a read voltage having a value smaller than VrH and a read voltage having a value larger than VrH. The LLR table is, for example, a table in which channel values are correlated for each set of one piece of hard bit data and multiple pieces of soft bit data.

The SB decoder 101 executes SB decoding (soft-decision decoding) using the received word. The SB decoder 101 decides a corresponding channel value from one piece of hard bit data and a plurality of pieces of soft bit data included in the received word by using the LLR table. The SB decoder 101 executes decoding with the channel value as an input, and outputs a soft-decision value (soft-decision output value) as a result. The soft-decision output value is, for example, a value obtained by expressing probability information indicating whether each bit is 0 or 1 in the form of LLR, and may be referred to as a posterior value (posterior value LLR).

Therefore, the SB decoding includes processing of determining a channel value (first likelihood information) corresponding to the read received word by using the LLR table (correspondence information) for each of the bits (read values) included in the received word (first received word) read from the nonvolatile memory 20, and processing of determining the posterior value LLR (posterior value likelihood information) by using the channel value.

The HB decoder 102 executes HB decoding (hard-decision decoding) using the received word. The HB decoder 102 executes decoding with the hard bit data as an input, and outputs a hard-decision value as a result of the decoding.

The HB decoder 102 executes HB decoding before SB decoding of the product code as in (A1) described above. The HB decoder 102 executes HB decoding in order to determine whether or not SB decoding is successful.

The determination unit 103 determines whether or not a termination condition of the iterative processing is satisfied. The termination condition of the iterative processing is, for example, a condition indicating that the number of iterations has reached the maximum value MaxA. The determination unit 103 determines whether or not SB decoding is successful. The determination unit 103 also determines whether or not a termination condition of the update processing is satisfied. The termination condition of the update processing is, for example, a condition indicating that the number of update times has reached the maximum value MaxB.

The update unit 104 executes the update processing of updating the LLR table. The update processing may be implemented by any method used in the related art. For example, in a case where the termination condition of the iterative processing of the SB decoding is satisfied and the SB decoding is failed, the update unit 104 estimates the LLR table and updates an LLR table T1 (first correspondence information) used in the SB decoding to an estimated LLR table T2 (second correspondence information).

Note that the SB decoder 101 uses the predefined LLR table as the LLR table T1 in the initial SB decoding. In a case where the SB decoding is failed and the LLR table is updated, the updated LLR table is used as the LLR table T1 in the subsequent SB decoding. By using the updated LLR table, the possibility of successful decoding can be enhanced.

The change unit 105 executes change processing of changing the parameter of the decoding processing. The change unit 105 first calculates an evaluation value that increases with increase in a difference between the LLR table T1 before the update and the LLR table T2 after the update.

The change unit 105 calculates, as the evaluation value, any one of the following values or a value obtained by combining two or more of the following values.
(M1) A distance between vectors in a case where the LLR tables are regarded as vectors: A distance between the LLR table T1 and the LLR table T2 may be calculated in any manner, but may be calculated by using, for example, a distance function that satisfies the axioms of a metric. For example, when assuming that vectors consisting of values of entries of the LLR tables T1 and T2 are v1 and v2, Euclidean distances of the vectors v1 and v2 may be used.
(M2) The number of entries whose signs are reversed out of the entries of the LLR table: This number corresponds to the number of entries whose signs of the likelihood information (LLR) do not match among the corresponding entries between the LLR table T1 and the LLR table T2.
(M3) For a set of elements i indicating the position where the sign is switched between entries of the LLR table, the number of different elements: Element i means that the sign is switched between the i-th entry and the (i+1)-th entry. i can take a value of 1 or more and (the number of entries—1) or less.

The LLR table T1 before the update is, for example, an LLR table used in the preceding SB decoding, but is not limited thereto. For example, the LLR table T1 before the update may be any one of one or more LLR tables used in past SB decoding for the read received word. The evaluation value may be calculated by using a plurality of LLR tables selected from a plurality of LLR tables used in past SB decoding for the read received word. For example, the change unit 105 may calculate an evaluation value of the difference between each of the plurality of LLR tables and the LLR table T2, and calculate a statistical value of the plurality of calculated evaluation values as a final evaluation value. The statistical value is, for example, a sum, an average value, a median value, or the like. The change unit 105 may calculate a flag as to whether or not the plurality of evaluation values is monotonically decreased in the order of calculation as the evaluation value, or may calculate a flag as to whether or not the difference between a maximum value and a minimum value among the evaluation values is smaller than a predetermined threshold value as the evaluation value. The LLR table used for calculating the evaluation value is stored in, for example, the data buffer 12.

Next, the change unit 105 executes change processing of changing, in accordance with the evaluation value, a parameter P1 (first parameter) to be used in the iterative processing and/or a parameter P2 (second parameter) to be used in the update processing. The parameter P1 is, for example, the maximum value MaxA for the number of iterations of SB decoding. The parameter P2 is, for example, the maximum value MaxB for the number of update times of the LLR table.

The parameter is not limited to the above, and any other parameter may be used. For example, in a case where the iterative processing has a function of ordered statistics decoding (OSD) that is performed in response to an instruction, the parameter P1 may be information representing the instruction about whether or not to perform the OSD. Another example of the parameter P2 will be described in a modification example.

The change unit 105 changes the parameter in accordance with a comparison result between the evaluation value and the threshold value. For example, the change unit 105 executes the change processing such that the maximum value MaxA decreases with increase in the evaluation value. In addition, the change unit 105 executes the change processing such that the maximum value MaxB increases with increase in the evaluation value.

For example, in a case where the evaluation value is equal to or greater than the threshold value, the change unit 105 changes the maximum value MaxA (parameter P1) for the number of iterations so as to decrease the maximum value MaxA, and changes the maximum value MaxB (parameter P2) for the number of update times so as to increase the maximum value MaxB. The change unit 105 does not change the parameter in a case where the evaluation value is less than the threshold value.

The change unit 105 may adjust a change amount of the parameter in accordance with the comparison result with two or more threshold values. For example, in a case where two threshold values TH1 and TH2 (value greater than TH1) are used, the change unit 105 may make the change amount for a case where the evaluation value is equal to or greater than the threshold value TH1 and is less than TH2, smaller than the change amount for a case where the evaluation value is equal to or greater than the threshold value TH2.

The parameter is desirably changed so as not to exceed an allowable latency. In one example, the change unit 105 changes the maximum value MaxA (parameter P1) for the number of iterations from “60” to “15”, and changes the maximum value MaxB (parameter P2) for the number of update times from “4” to “16”. In this example, the maximum latency before and after the change remains at “240” (60×4, 15×16).

As described above, in a case where the evaluation value (difference) is large, the maximum value MaxB for the number of update times is increased. This makes it possible to estimate the LLR table closer to the optimal LLR table. Additionally, in a case where the evaluation value (difference) is large, the maximum value MaxA for the number of iterations is decreased. As a result, it is possible to avoid a situation in which the latency of the entire decoding processing increases and exceeds the allowable latency.

Note that, in a case where there is a margin for the allowable latency or the like, the change unit 105 may execute only a change to increase the maximum value MaxB (parameter P2) for the number of update times.

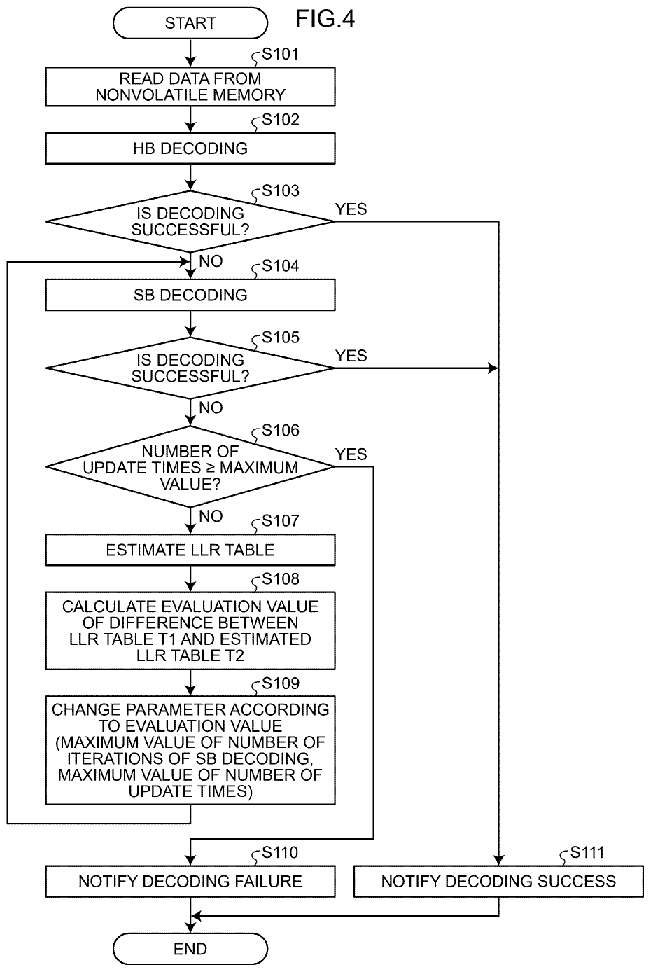

Next, a procedure of the decoding processing by the memory system 1 of the present embodiment will be described. FIG. 4 is a flowchart illustrating an example of the decoding processing according to the present embodiment.

The control unit 11 reads the error correction code to obtain the received word from nonvolatile memory 20 (step S101). The control unit 11 transfers the read received word to the read information memory 121 and stores the read received word.

Next, the HB decoder 102 of the decoder 18 executes HB decoding (step S102). The decoder 18 determines whether or not the decoding (HB decoding) is successful (step S103). In a case where the decoding is failed (step S103: No), the SB decoder 101 of the decoder 18 executes SB decoding (step S104).

The SB decoding in step S104 refers to processing (iterative processing) of repeatedly executing the SB decoding with the set maximum value MaxA as an upper limit of the number of iterations. In the SB decoding, the LLR table T1 is used. As described above, in the initial SB decoding, the predefined LLR table is used as the LLR table T1. In the second and subsequent SB decoding, the LLR table T1 updated by the update processing is used.

The determination unit 103 of the decoder 18 determines whether or not the SB decoding is successful (step S105). In a case where the decoding is failed (step S105: No), the determination unit 103 of the decoder 18 determines whether or not the number of times of the update processing (the number of update times) is equal to or greater than the maximum value MaxB (step S106).

In a case where the number of update times is less than the maximum value MaxB (step S106: No), the update unit 104 executes the update processing, and estimates the LLR table T2 (step S107).

The change unit 105 calculates the evaluation value indicating the difference between the LLR table T1 and the estimated LLR table T2 (step S108). The change unit 105 changes the parameter in accordance with the calculated evaluation value (step S109). For example, in a case where the evaluation value is equal to or greater than the threshold value, the change unit 105 decreases the maximum value MaxA (parameter P1) for the number of iterations of the SB decoding, and increases the maximum value MaxB (parameter P2) for the number of update times. The change unit 105 does not change the parameter P1 and the parameter P2 in a case where the evaluation value is less than the threshold value. After step S109, the processing returns to step S104, and SB decoding is further executed.

In a case where it is determined in step S106 that the number of update times is equal to or greater than the maximum value MaxB (step S106: Yes), the decoder 18 notifies an external control unit or the like of the failure of the decoding (step S110), and ends the decoding processing.

In a case where it is determined in step S103 or step S105 that the decoding is successful (step S103: Yes, step S105: Yes), the decoder 18 notifies an external control unit or the like of a decoding word together with the successful of the decoding (step S111), and ends the decoding processing.

### First Modification Example

A first modification example using parameters different from those in the above embodiment will be described. In the present modification example, termination information is used as the parameter P2 for the update processing. The termination information is information designating whether or not to terminate the update processing.

The termination information may be represented by a flag that takes a binary value indicating truth or falsehood (for example, “1” for True and “0” for False). In a case where the termination information is set to True, the execution of the update processing is terminated. In a case where the termination information is set to False, the update processing is not terminated and is continuously executed. In the termination information, a value of False (indicating that termination is not performed) is set as an initial value.

In the present modification example, in accordance with the evaluation value, the change unit 105 changes the maximum value MaxA (parameter P1) for the number of iterations of SB decoding and changes termination information (parameter P2).

In one example, in a case where the evaluation value is less than the threshold value, the change unit 105 changes the termination information (parameter P2) to True, and sets the maximum value MaxA (parameter P1) for the number of iterations of SB decoding to the maximum value of the number of iterations at which the decoding processing is completed within the allowable latency.

In a case where the evaluation value is equal to or greater than the threshold value, the change unit 105 sets the termination information (parameter P1) to False (not changed from the initial value), and sets the maximum value MaxA (parameter P1) for the number of iterations of SB decoding to, for example, a default value.

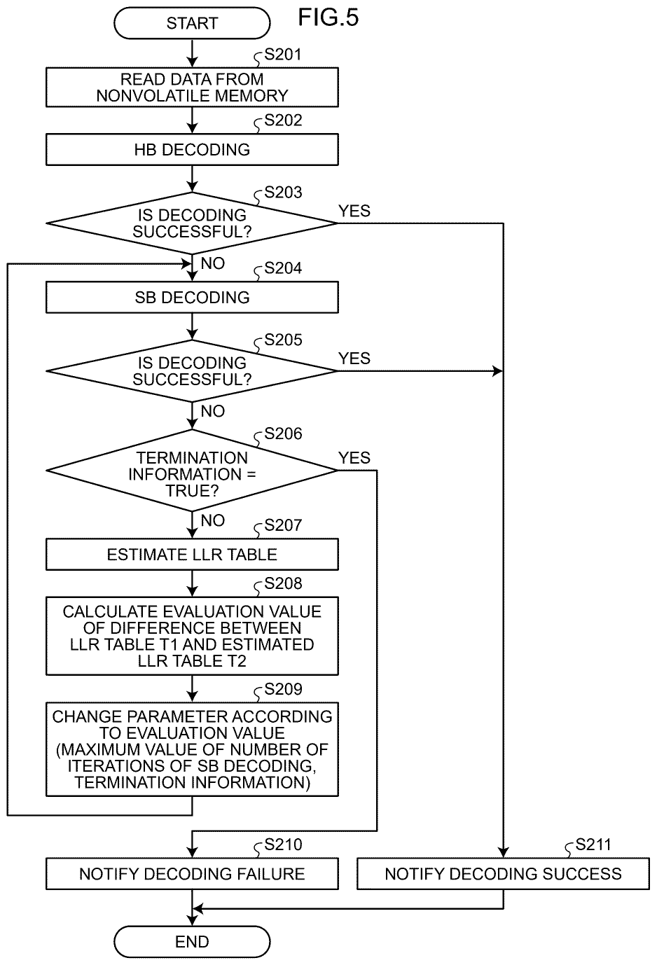

Next, a procedure of the decoding processing by the memory system 1 of the present modification example will be described. FIG. 5 is a flowchart illustrating an example of the decoding processing according to the present modification example.

In the modification example, steps S206 and S209 are different from those in FIG. 4 illustrating the decoding processing of the above-described embodiment. The differences from FIG. 4 will be described below.

In step S206, the determination unit 103 determines whether or not the termination information is set to True (step S206). In a case where the termination information is set to True (step S206: Yes), the decoder 18 notifies an external control unit or the like of the failure of the decoding (step S210), and ends the decoding processing. In a case where the termination information is set to False (step S206: No), the processing in and after step S207 is executed.

In step S209, the change unit 105 changes the parameter in accordance with the calculated evaluation value (step S209). For example, in a case where the evaluation value is less than the threshold value, the change unit 105 changes the termination information (parameter P2) to True, and sets the maximum value MaxA (parameter P1) to the maximum value of the number of iterations at which the decoding processing is completed within the allowable latency. In a case where the evaluation value is equal to or greater than the threshold value, the change unit 105 sets the termination information (parameter P1) to False, and sets the maximum value MaxA (parameter P1) of the number of iterations of SB decoding to a default value.

### Second Modification Example

In a second modification example, an example in which an evaluation value is used for purposes other than the parameter change will be described.

In a case where the evaluation value exceeds the threshold value, the decoder 18 may output information (determination result) indicating that the evaluation value exceeds the threshold value. By referring to the output determination result, the memory controller 10 can adaptively select processing for received words read out in subsequent operations.

In a case where the determination result indicating that the evaluation value exceeds the threshold value is output, the memory controller 10 replaces the predefined LLR table with the LLR table T2 finally obtained by the update processing. The evaluation value in this case may be an evaluation value based on a difference between the predefined LLR table and the LLR table T2 finally obtained by the update processing. As a result, the LLR table closer to the optimal LLR table can be used in the subsequent decoding processing. Thus, the error correction can be executed with higher accuracy.

In a case where the determination result indicating that the evaluation value exceeds the threshold value is output, the memory controller 10 may rewrite the data, which corresponds to the received word read as a target of the decoding processing, onto another storage area in the nonvolatile memory 20. A situation in which the evaluation value exceeds the threshold value can be determined as indicating a high bit error rate of the data. Therefore, it is possible to reduce the bit error rate of the data by rewriting.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An error correction apparatus comprising:
a controller configured to
determine first likelihood information being a piece of likelihood information corresponding to a first received word as a target of decoding among multiple pieces of likelihood information, the first likelihood information being determined by using first correspondence information in which read values included in a received word and the multiple pieces of likelihood information are correlated with each other,
execute iterative processing of repeating soft-decision decoding using the first likelihood information until a termination condition is satisfied,
execute update processing of updating the first correspondence information to second correspondence information in a case where the termination condition is satisfied and the soft-decision decoding is failed,
calculate an evaluation value that increases with increase in a difference between the first correspondence information and the second correspondence information,
execute change processing of changing, in accordance with the evaluation value, at least one of a first parameter to be used in the iterative processing or a second parameter to be used in the update processing, and
execute further the iterative processing after executing the change processing.

2. The error correction apparatus according to claim 1, wherein the first parameter represents a maximum value of the number of iterations of the iterative processing.

3. The error correction apparatus according to claim 2, wherein the controller is configured to execute the change processing by which the maximum value is decreased with increase in the evaluation value.

4. The error correction apparatus according to claim 1, wherein the second parameter represents a maximum value of the number of executions of the update processing.

5. The error correction apparatus according to claim 4, wherein the controller is configured to execute the change processing by which the maximum value is increased with increase in the evaluation value.

6. The error correction apparatus according to claim 1, wherein
the iterative processing includes ordered statistics decoding (OSD) performed in response to an instruction, and
the first parameter is information representing the instruction about whether or not to perform the OSD.

7. The error correction apparatus according to claim 1, wherein the second parameter is information designating whether or not to terminate the update processing.

8. The error correction apparatus according to claim 1, wherein the controller is configured to calculate, by using a distance function satisfying axioms of a metric, the evaluation value based on a distance between the first correspondence information and the second correspondence information.

9. The error correction apparatus according to claim 8, wherein the evaluation value based on the distance is Euclidean distance.

10. The error correction apparatus according to claim 1, wherein the controller is configured to calculate the evaluation value indicating the number of corresponding entries whose signs of likelihood information do not match between the first correspondence information and the second correspondence information.

11. The error correction apparatus according to claim 1, wherein the controller is configured to, when the evaluation value exceeds a threshold value, output information indicating that the evaluation value exceeds the threshold value.

12. The error correction apparatus according to claim 1, wherein the controller the controller is configured to, when the evaluation value exceeds a threshold value, replace the first correspondence information to be used as a predefined value with the second correspondence information obtained by the update processing.

13. The error correction apparatus according to claim 1, wherein the controller is configured to
read the first received word from a nonvolatile memory in which data and an error correction code generated by using the data are stored, and
rewrite the data corresponding to the first received word within the nonvolatile memory when the evaluation value exceeds a threshold value.

14. An error correction method implemented by a computer, the error correction method comprising:
determining first likelihood information being a piece of likelihood information corresponding to a first received word as a target of decoding among multiple pieces of likelihood information, the first likelihood information being determined by using first correspondence information in which read values included in a received word and the multiple pieces of likelihood information are correlated with each other;
executing iterative processing of repeating soft-decision decoding using the first likelihood information until a termination condition is satisfied;
executing update processing of updating the first correspondence information to second correspondence information in a case where the termination condition is satisfied and the soft-decision decoding is failed;
calculating an evaluation value that increases with increase in a difference between the first correspondence information and the second correspondence information;
executing change processing of changing, in accordance with the evaluation value, at least one of a first parameter to be used in the iterative processing or a second parameter to be used in the update processing; and
executing further the iterative processing after executing the change processing.

15. The error correction method according to claim 14, wherein the first parameter represents a maximum value of the number of iterations of the iterative processing.

16. The error correction method according to claim 14, wherein the second parameter represents a maximum value of the number of executions of the update processing.

17. A memory system comprising:
a nonvolatile memory configured to store data and an error correction code generated by using the data; and
a memory controller configured to
read a received word from the nonvolatile memory,
determine first likelihood information being a piece of likelihood information corresponding to a first received word as a target of decoding among multiple pieces of likelihood information, the first likelihood information being determined by using first correspondence information in which read values included in the received word read from the nonvolatile memory and the multiple pieces of likelihood information are correlated with each other,
execute iterative processing of repeating soft-decision decoding using the first likelihood information until a termination condition is satisfied,
execute update processing of updating the first correspondence information to second correspondence information in a case where the termination condition is satisfied and the soft-decision decoding is failed,
calculate an evaluation value that increases with increase in a difference between the first correspondence information and the second correspondence information,
execute change processing of changing, in accordance with the evaluation value, at least one of a first parameter to be used in the iterative processing or a second parameter to be used in the update processing, and
execute further the iterative processing after executing the change processing.

18. The memory system according to claim 17, wherein the nonvolatile memory is a NAND memory.

19. The memory system according to claim 17, wherein the memory controller is connected to a host via an interface compliant to a peripheral component interconnect (PCI) express standard, the host serving to transmit a write request and a read request on the nonvolatile memory.

20. The memory system according to claim 17, the error correction code is a Bose-Chaudhuri-Hocquenghem (BCH) code, a Reed-Solomon (RS) code, or a generalized low density parity check (GLDPC) code.
